(19) United States
(12) Patent Application Publication
(10) Pub. No.: US 2021/0215750 A1
(43) Pub. Date: Jul. 15, 2021

(54) METHOD AND SYSTEM FOR FAULT DETECTION

(71) Applicant: ENICS AG, Zurich (CH)

(72) Inventor: Kristian FEDERLEY, Sipoo (FI)

(21) Appl. No.: 17/054,848

(22) PCT Filed: May 10, 2019
(86) PCT No.: PCT/EP2019/062037

§ 371 Date: Nov. 12, 2020

(30) Foreign Application Priority Data
May 18, 2018 (FI) 20185463

(51) Int. Cl. G01R 31/00; G01R 29/08; G01R 31/315

(52) U.S. Cl. CPC G01R 31/002; G01R 31/315; G01R 29/0814

(57) ABSTRACT

A method wherein faults are detected by measuring electromagnetic emission from a device under test which is placed into different operating states. Electromagnetic emission signals are measured from the device for each operating state by obtaining a time-domain result. The measured signals are processed by digitizing and converting the signal from time-domain into frequency domain. The result is compared with a result of a non-fault device. A fault is detected if there is a sufficient difference between the compared results. The system includes one or more inductive sensors and one or more amplifiers. A digital processing unit in the system includes an analog-to-digital converter for digitizing measured signals, an analyzer for transforming the digital signals into frequency components, a comparator for comparing the frequency components to those of a non-fault device, and a memory for storing the measurement results.

### TECHNICAL FIELD

The invention is concerned with a method and system for detecting faults in devices by measuring electromagnetic emission.

### BACKGROUND

Faults in electronic and mechanical devices can occur for many different reasons, like wear or a defect of a part. Mechanical machines are designed to operate inside tolerance values and in specific conditions. Operating mechanical or electronic devices with incorrect settings can lead to a fault causing system breakdown. In addition, a system that does not work optimally consumes more resources, produces less or even wrong output, or experience more wear than a machine working on correct settings.

Traditionally, testing is done by verifying a device with functionality tests. In such tests, various electrical signals are measured from the device by accessing either specifically built-in test points or device connectors. A thorough understanding of device functionality is required to define expected measurement results. Also, specialised instrumentation as well as methods for accessing the test points and connectors are needed. Test point access is typically made with a custom-built bed of nails, which is dedicated for one specific device. Developing the bed of nails and device specific instrument configuration is slow and costly.

There are also non-contact test methods where various phenomena emitted by the device are measured. Such phenomena can consist of e.g. electrical emission or sound.

There are some known approaches for using electromagnetic emissions from devices as a basis for detecting faults. Several of the approaches utilise an external signal source which is used to inject emission signal into the device to be tested. There are also approaches where natural emission from a device is used as a measurement basis.

U.S. Pat. No. 5,006,788 discloses a non-contact method and an apparatus for detecting faults in a device. The method describes activating a device to be tested and measuring changing magnetic fields within the device with sensor probes where magnetic fields induce corresponding currents. The electromagnetic emission is measured with a network of sensors. A scanning system is used to address each sensor and forward measured emission into a receiver tuned into a specific frequency. The receiver then passes the received signal into a signal processor for frequency domain conversion. Results are then compared to those measured from a known good device to detect faults in case there are differences in detected radiation.

The invention presented requires use of a tuned receiver which records emissions on a single frequency only. As faulty units may have emissions in a different frequency than a working one, a number of measurements are needed in order to verify that no extra emissions are present.

U.S. Pat. No. 5,406,209 also discloses a method and an apparatus to detect faults in a device with no-contact testing. The method comprises disposing at least one electromagnetic emission sensing probe close to the device to be tested, measuring electromagnetic emission from the device, creating a time domain representation of the measured emission and comparing measured emission from the device to be measured to those recorded from a known good one. Time domain information contains phase information that can be made use of but using phase differences is computationally expensive. Phases can also change due to changes in operating environment like in temperature or humidity.

International patent application No. WO 2005/081000 discloses another non-contact method for testing electronic devices. At least one sensing probe is used to measure electromagnetic emission from a device. The measurements are transformed into frequency domain but also transformed into a second frequency domain which is in the audible frequency range. A human operator is then used to listen to the audible range signals from the device under test and compare them to those measured from a known good device.

The approach taken in this solution to use a human operator to detect faults has its drawbacks. It is difficult to keep fault criteria consistent when operators change and humans tend to make errors e.g. when tired. Using audible signals in fault detection is also susceptible to environmental issues like background noise.

European patent application No. 0,527,321 discloses a method for detecting faults in electronic devices which contains both contact and non-contact parts. A device is electrically tested using its normal input and output connectors for finding discrepancy to expected results. Electromagnetic emission from the device is measured and compared to information measured from a known good device. Electrical emission measurement is done using a matrix of antennas like in other inventions listed above. Since in this solution, electrical measurements are retained, one needs to develop a good understanding of device behaviour and what are expected outputs to defined inputs. Furthermore, a case specific set of instruments are needed to be able to exercise the device under test and to observe its behaviour.

The object of the present invention is a solution that avoids the drawbacks of prior art.

### SUMMARY

With the method of the invention, faults are detected by measuring electromagnetic emission from a device under test to be monitored. The device is placed into one or more of its operating states, such as its normal operating states. Electromagnetic emission signals are measured from the device at each operating state of the device by obtaining a result in time-domain. The measured signals are processed into a result for the device to be monitored by digitizing and converting the resulting signal in time-domain into frequency domain. The result of the device to be monitored are compared with a result of a non-fault device. A fault is detected in the device to be monitored if there is a sufficient difference between the compared results.

The system of the invention comprises one or more inductive sensors for performing measurements of electromagnetic emission from a device in one or more operating states and one or more amplifiers. A digital processing unit in the a system comprises an analog-to-digital converter for converting measured signals to digital form, an analyzer for transforming the digital signals into frequency components, a comparator for comparing the frequency components from said device to those obtained in a corresponding way from a non-fault device, and a memory for storing the measurement results of the measured signals processed in the foregoing steps.

The preferable embodiments of the invention have the characteristics of the sub claims.

Thus, the measured electromagnetic emission signals are converted by e.g. Fast Fourier Transform (FFT) into frequency-domain by dividing the digitized wave form curve in into a number of frequency components for obtaining a frequency spectrum.

The electromagnetic emission signals from the device are measured by using one or more inductive sensors, each of which is placed in different positions at and close to the device for different operating states to be measured. The measurements are preferably performed in each operating state of the device of each position of the sensor.

If the electromagnetic emission signals are measured from different operating states of the device by using a single inductive sensor, it is moved in the x-y direction with e.g. one or more motors.

The invention provides new methods for testing electronic printed circuit boards and other devices or units in production environment.

This invention is based on measuring and analysing electromagnetic emission from the devices to be measured. Normal device operation is used to create the emission. No external emission sources are used for injection into the device. The device is placed into various operating states, e.g. to no load and full load states, and emissions from those states are measured. Measurement results are then converted into frequency domain with Fast Fourier Transform and compared to those of known good working devices. A fault is detected if the difference between the results is larger than a pre-defined limit.

The method presented in the invention is advantageous as it does not require any deep knowledge of the device functionality. Measuring emissions signals in different operating states is enough. The same instrumentation can be used to measure all devices as opposed to functional testing, which requires case specific instrumentation sets. A custom build bed of needles is not needed either.

In the following, the invention is described by some example embodiments by referring to figures. The invention is not restricted to the details of these embodiments.

### FIGURES

FIG. 1 is a block diagram of the system of the invention

FIG. 2 is a side view of an implemented sensor placement over a device under test

FIG. 3 is a top view of an implemented sensor placement over a device under test

FIG. 4 illustrates the way of measurement result comparison in the invention

FIG. 5 is a flow scheme that illustrates how the measurements in the inventions are performed

FIG. 6 is a flow scheme that illustrates how faults of a device under test are detected

### DETAILED DESCRIPTION

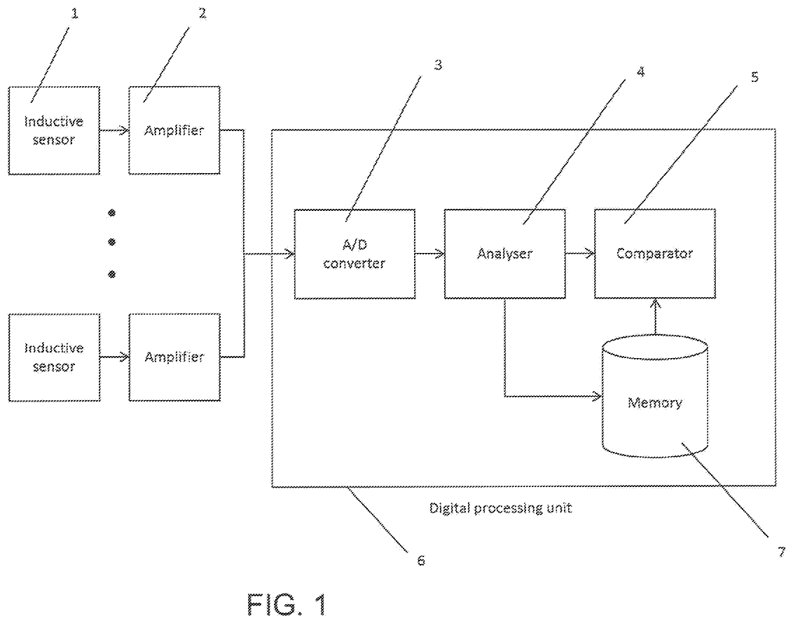

FIG. 1 is a block diagram of the apparatus of the invention.

The system comprises one or more inductive sensors 1 for measuring and recording electromagnetic emission from a device (not shown) in one or more operating states and from one or more positions. Since the measured signals received from the sensors have a low amplitude, they are amplified with one or more amplifiers 2.

The amplified sensor signals are recorded and processed in a digital processing unit 6. The signal received by the digital processing unit 6 is in the form of an analog wave form curve in time-domain. An analog-to-digital (A/D) converter 3 therefore, converts the recorded signals into digital form.

Computation is performed in the further signal processing in order to analyze the measured emission.

A signal can be converted between time and frequency domains with a pair of mathematical operators called a transform. An example is the Fourier transform, which converts a time function of a signal into a sum of sine waves of different frequencies, each of which represents a frequency component.

In the embodiment of the invention, an analyzer 4 divides the digital signals obtained from the A/D converter 3 by transforming them into frequency components using Fast Fourier Transformation (FFT).

This process, in effect, converts a waveform in the time domain that is difficult to describe mathematically into a more manageable series of sinusoidal functions that when added together, exactly reproduce the original waveform. Plotting the amplitude of each sinusoidal term versus its frequency creates a power spectrum, which is the response of the original waveform in the frequency domain. Essentially, Fourier Transform takes a signal and breaks it down into sine waves of different amplitudes and frequencies.

A ‘spectrum’ of frequency components is the frequency domain representation of the signal and is called a spectrogram or a frequency spectrum. Such a frequency spectrum is thus formed as a visual representation of the spectrum of frequencies of the measured signal as they vary with time or some other variable. The frequency spectrum of the measured emission signal shows the distribution of the amplitudes and phases of each frequency component against frequency. The formed frequency spectrum, provides information of how the energy of the signal is distributed to different frequencies.

Some faults in devices to be monitored affect the shape of the spectrum. For example, the spectral peak is a feature that can be extracted from the measured signal. Different features are useful in different scenarios.

Conversion of the digital signal into frequency domain is done with a microprocessor in the digital processing unit 6 with a frequency spectrum with distinct frequency components as a result. The conversion is performed with a software program in an analyser 4 in the microprocessor, which then stores the frequency spectrum consisting of the distinct frequency components in a memory 7 connected to the microprocessor.

When one or more frequency spectra obtained from non-faulty devices have been stored in a memory they can be compared with the frequency spectrum of the device under test by a software program in a comparator 5, which also is comprised in the microprocessor and which has a connection to a memory 7.

A comparator 5 is used to compare the frequency components obtained from a device under test 8 to those previously recorded and obtained in a corresponding way from a non-fault device.

The comparator 5 indicates a fault in the device under test if there is a sufficient pre-defined difference between the non-faulty signals and the signals from the device under test.

The results obtained from the analyser 4 and from the comparator 5 are then stored in a memory 7.

The A/D converter 3, the microprocessor comprising the analyser 4 and the comparator, and furthermore the memory 7 are components of the digital processing unit 6.

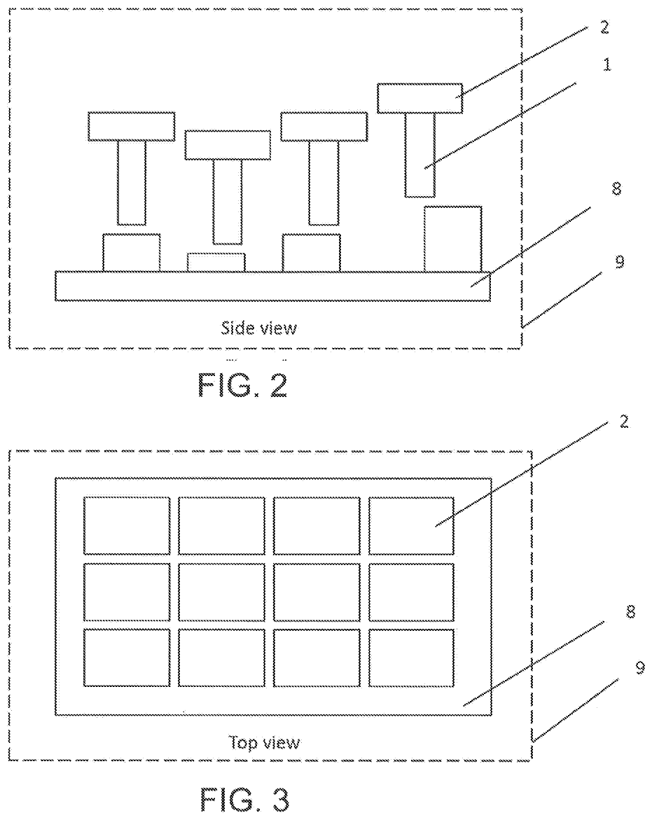

FIG. 2 is a side view of sensor placement over a device 8 to be monitored.

As was presented in connection with FIG. 1, the system comprises one or more inductive sensors 1 for measuring signals, which are amplified with one or more amplifiers 2.

In case only one sensor 1 is used, the sensor position can be moved in the XY plane for performing measurements in several positions. The Z-direction, i.e. sensor height, is preferably adjusted to be as close to parts of the device 8 (see FIGS. 2 and 3) as possible.

The Sensors 1, the amplifiers 2, and the device 8 under test are housed in a Radio Frequency (RF) shielded enclosure 9 to keep external interference as low as possible.

FIG. 3 is a top view of a possible sensor placement over device. In FIG. 3, the sensors 2 are thus seen from above.

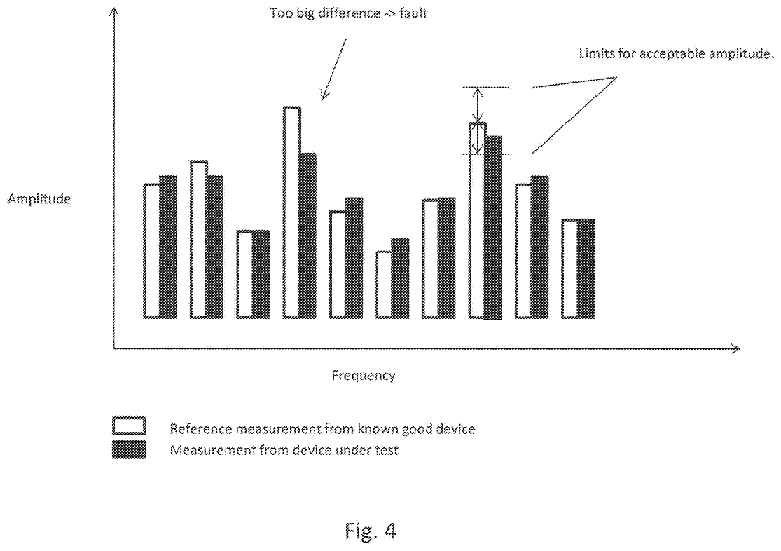

FIG. 4 illustrates the way of measurement result comparison in the invention.

In the invention for fault detection, emission signals from a non-fault device and a device under test to be monitored are compared in frequency domain by means of a frequency spectrum presenting the amplitude values (y-axle of FIG. 4) at each frequency component (x-axle of FIG. 4) as a bar chart.

The frequency spectrum is thus the amplitude versus its frequency and is the response of the original waveform in the frequency domain. The signal has thus been broken down into sine waves of different amplitudes and frequencies. Some faults in devices to be monitored affect the shape of the spectrum.

When one or more frequency spectra obtained from non-faulty devices have been stored in a memory they can be compared with the frequency spectrum of the device under test by a software program to detect faults.

Before starting the detection, an amplitude value for the frequency spectrum is pre-defined as a limit value as an indication for a fault. This limit value defines a limit for the biggest allowable difference between the amplitude value at a given frequency for a non-fault device and the amplitude value at a given frequency for the device under test.

When the limit value is the same at each frequency, the method is simpler than when the limit value is frequency dependent. It is, however, also possible to define separate limit values for each frequency or for some frequencies. Still further, it is possible to define separate limit values for different operational states and positions.

The limit value comparison is illustrated example wise in FIG. 4, wherein the left bar (white) at each frequency presents the amplitude value at that frequency of a known good device and the bar (black) on the right side at each frequency presents the amplitude value at that frequency of a device under test.

Let us assume that the length of the double arrow illustrates the limit value being the maximum allowed difference between the amplitude value at a given frequency for a non-fault device and the amplitude value at a given frequency for the device under test.

Then a fault can be detected at the fourth frequency value component of the chart since the difference is exceeded. All other limits are within the tolerance in FIG. 4.

For example, the lines below and above the double arrows at the eighth bar indicates values that would be considered to indicate a fault if exceeded. A fault is detected if the amplitude value for some frequency is outside the limit value (lower or higher).

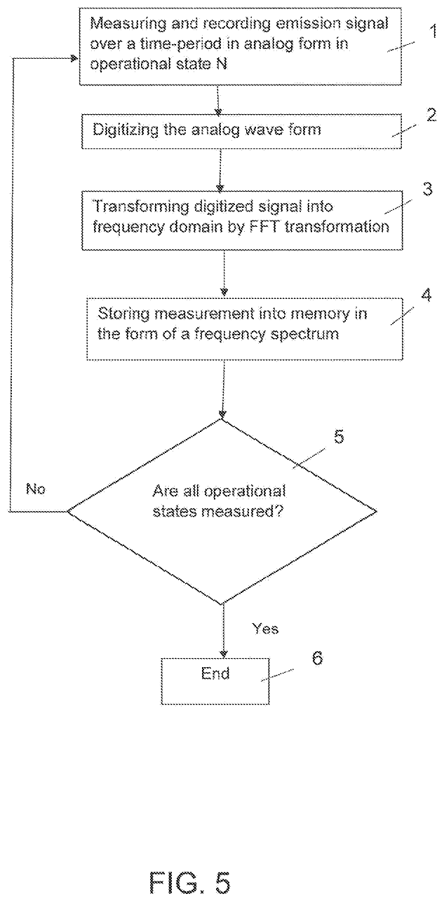

FIG. 5 is a flow scheme that illustrates how the measurements themselves in the inventions are performed.

The following flow is performed for both a known non-fault device and for the device under test.

In step 1, the electromagnetic emission signal from the device is measured and recorded over a time period in analog form. This is performed with an inductive sensor 1 of FIG. 1 by placing the device on a given position over the device. An analog signal wave form curve in time-domain is obtained in a given operating state of the device for the measured electromagnetic emission signal. The recording practically takes place in a working memory. The signals, which can constitute signals in several operating states of the device from many positions of the device received in step 1 are amplified with the amplifier 2.

In step 2, the wave form curve is digitized with the Analog-to-Digital converter (A/D) 3 of the digital processing unit 6 of FIG. 1.

In step 3, each digitized signal from step 2 is transformed in the analyser 4 into frequency domain for obtaining a frequency spectrum. The transform is preferably performed with Fast Fourier Transform (FFT), in which the digitized wave form curve in time-domain is divided into a number of frequency components for obtaining a frequency spectrum (a spectrum in frequency-domain) showing how the emission signal measured is distributed over the different frequency components.

In step 4, the resulting frequency spectrum is stored in a temporary or other memory in the digital processing unit 6. There can be many frequency spectra representing measurements from many positions of the device in each operating state.

The steps of 1-4 are repeated for all other operating states as long as it is stated in step 5 that there are still operating states to be measured for a given position, while the method continues with step 6 when it is stated in step 5 that all operating states are measured for all positions to be measured.

The repeated steps of steps 1-4 are performed by having several inductive sensors 1 of FIG. 1 by placing them close to the device on different positions over the device. Alternatively, only one sensor is used, which is moved over the device for performing measurements in different operating states in different positions. Naturally, mixed embodiments are possible in that a part of the operating states can be measured by moving a sensor over different positions, while other positions can be measured by having fixed sensors.

As said above, steps 1-4 are performed for both a known non-fault device and a device under test.

Step 6 ends the measurement.

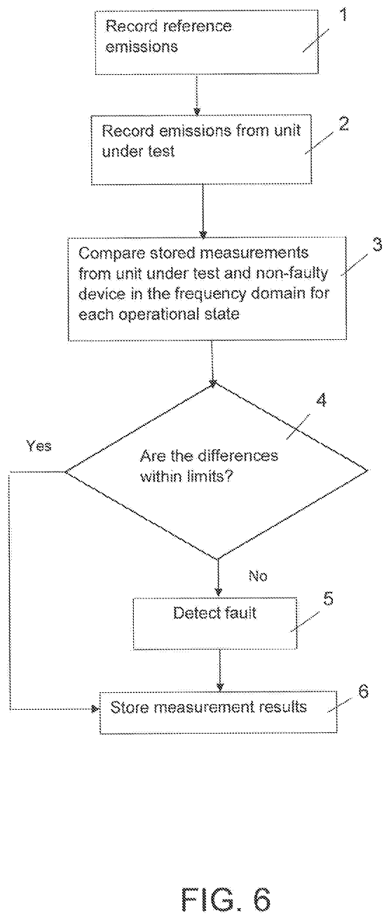

FIG. 6 is a flow scheme of the invention for detecting faults of a device by analyzing emission signals from a device under test.

The measurement flow of FIG. 5 is preferably first performed for a known non-fault device in step 1 of FIG. 6, whereby an electromagnetic emission signal from at least one non-fault device is first recorded to represent reference emission measurements and stored in the memory of the apparatus of the invention.

The same flow is then performed for the device under test, whereby electromagnetic emission signals from the device under test (or generally from a unit under test) is recorded and stored in the memory of the apparatus of the invention as illustrated by step 2 of FIG. 6.

As explained above in connection with FIG. 4, a pre-defined frequency limit was defined for indicating a fault. This limit is used in a comparison in step 3 to determine whether the device under test is a faulty device.

If it is stated in step 4 that the limit value is not exceeded, no fault is detected and the device under test is determined to be a working device and the result as a working device is stored in step 6.

If it is stated in step 4 that the limit value, in fact, is exceeded, i.e. if the difference between the amplitude value at a frequency component derived from an emission signal measured from a non-fault device and the amplitude value at a frequency component value derived from an emission signal measured from a device under test to be monitored exceeds the pre-defined limit value defined for that frequency component, a fault is detected in step 5 (i.e. the amplitude value is above or under an allowable value), as a result of the comparison in step 3 and the device under test is determined to be a faulty device and the result as a faulty device is stored in step 6.

There can be a common limit for all the frequency components or they can be different for each frequency component, operating state and/or position. Thus, there are several comparisons performed for each frequency spectrum pair of a device under test and a non-faulty device. The comparison is to be performed by comparing the stored frequency components measured from the known non-faulty device and the device under test and comparison results are stored in the memory 7 in step 6.

1.-7. (canceled)

8. A method for fault detection by measuring electromagnetic emission from a device under test to be monitored, the method comprises:
a) placing the device into two or more of its operating states,
b) measuring electromagnetic emission signals from the device at each placed operating state of the device and obtaining a result in time-domain,
c) processing the measured signals into a result for the device to be monitored by digitizing and converting the resulting signal in time-domain into frequency domain,
d) comparing the result of the device to be monitored with earlier measured corresponding results of a non-fault device for the same operating states, and
e) detecting a fault in the device to be monitored if there is a sufficient difference between the compared results.

9. The method according to claim 8, further comprising converting the measured electromagnetic emission signals into frequency-domain by dividing the digitized wave form curve in into a number of frequency components for obtaining a frequency spectrum.

10. The method according to claim 9, wherein the converting is performed by Fast Fourier Transform, FFT.

11. The method according to claim 9, further defining predefining a limit as an amplitude value that indicates a fault for one or more frequency components of the frequency spectrum.

12. The method according to claim 8, further comprising measuring the electromagnetic emission signals from the device by using one or more inductive sensors, which is/are placed close to the device in given positions of the device.

13. The method according to claim 12, further comprising measuring the electromagnetic emission signals at each position of the device and in several operating states for each position by using one or more inductive sensors.

14. The method according to claim 8, further comprising measuring the electromagnetic emission signals from different operating states of the device by using a single inductive sensor and by moving the inductive sensor in the x-y direction.
